(19) United States
(12) Patent Application Publication
(10) Pub. No.: US 2025/0380379 A1
(43) Pub. Date: Dec. 11, 2025

(54) SERVER, LIQUID COOLING SYSTEM AND LEAKAGE PROTECTION DEVICE THEREOF

(71) Applicant: SHENZHEN ENVICOOL TECHNOLOGY CO., LTD., Shenzhen (CN)

(72) Inventors: Xiaoxin XU, Shenzhen (CN); Xiaolei AI, Shenzhen (CN); Xiaojin CHENG, Shenzhen (CN); Zhen XIONG, Shenzhen (CN); Feng LV, Shenzhen (CN)

(73) Assignee: SHENZHEN ENVICOOL TECHNOLOGY CO., LTD., Shenzhen (CN)

(21) Appl. No.: 18/814,636

(22) Filed: Aug. 26, 2024

(30) Foreign Application Priority Data
Jun. 7, 2024 (CN) 202421308083.6

(51) Int. Cl. H05K 7/20

(52) U.S. Cl. CPC H05K 7/20272; H05K 7/20763

(57) ABSTRACT

A server, a liquid cooling system and a leakage protection device thereof are provided. The leakage protection device includes a suction apparatus, multiple liquid collecting components and multiple suction pipelines. The multiple liquid collecting components are located at different positions of a liquid-cooling heat-dissipation module, respectively, to collect a leaking liquid of the liquid-cooling heat-dissipation module. The multiple suction pipelines are arranged corresponding to the liquid collecting components, respectively. A first end of each suction pipeline is located inside the corresponding liquid collecting component, and a second end thereof is connected to the suction apparatus, wherein at least one suction pipeline has a blocking component at the first end thereof, and the blocking component has a property that can prevent passage of gas and allow passage of the leaking liquid from the corresponding liquid collecting component.

### CROSS REFERENCE TO RELATED APPLICATIONS

The present application claims priority to Chinese Patent Application No. 202421308083.6, titled “SERVER, LIQUID COOLING SYSTEM AND LEAKAGE PROTECTION DEVICE THEREOF”, filed on Jun. 7, 2024 with the China National Intellectual Property Administration, which is incorporated herein by reference in its entirety.

### FIELD

The present disclosure relates to the technical field of heat dissipation, and in particular to a server, a liquid cooling system and a leakage protection device thereof.

### BACKGROUND

With the increase of the power density of servers, there is a high requirement for heat dissipation. Compared with air cooling heat exchange, liquid cooling heat exchange can provide higher heat exchange efficiency to meet heat exchange requirements of servers. At present, the liquid cooling for servers mainly adopts cold plate liquid cooling, also known as a liquid cooling plate. The liquid cooling plate exchanges heat with a high heat-generating element of a server, and then quickly transfer heat to the outside of the server by being connected to a heat exchange device through a liquid inflow pipe and an outflow pipe.

During the operation of the server, a leakage may occur at positions such as a liquid cooling plate, liquid inflow and outflow pipes, or the welding joints between the liquid cooling plate and the liquid inflow and outflow pipes due to fatigue, vibration, etc. If the electronic components of the server come into contact with the leaking high-pressure liquid, a fault such as a short circuit may occur. Therefore, it is necessary to detect whether there is a leakage in the liquid-cooling heat-dissipation module, and perform an operation such as shutdown in time when a leakage is detected. To increase the allowable processing time, a liquid collecting component can be installed at locations of the liquid cooling system where a leakage is prone to occur, and connected to a pump through pipelines. The pump can start to draw the leaking liquid collected in the liquid collecting component.

In the process of implementing the present invention, the inventor found that there are at least the following problems in the existing technology.

Multiple liquid collecting components are usually located corresponding to various leakage positions of the liquid-cooling heat-dissipation module. The multiple liquid collecting components are connected to a single pump through pipelines, that is, the pump is connected to multiple branches to suction leaking liquid. However, if the leakage only occurs in positions corresponding to some of the multiple branches while there is no leakage for the other branches, the pump has to simultaneously draw liquid or air through all branches during operation, making it difficult to effectively draw the leaking liquid.

### SUMMARY

In view of the above, an object of the present disclosure is to provide a server, a liquid cooling system and a leakage protection device thereof, which are structured to effectively solve the problem that it is difficult to effectively draw the leaking liquid simultaneously in multiple branches.

In order to achieve the above object, the following technical solutions are provided in the present disclosure.

A leakage protection device, including:
a suction apparatus;
multiple liquid collecting components, which are located at different positions of a liquid-cooling heat-dissipation module, respectively, to collect a leaking liquid of the liquid-cooling heat-dissipation module; and
multiple suction pipelines, which are arranged corresponding to the liquid collecting components, respectively, wherein
a first end of each suction pipeline is located inside the corresponding liquid collecting component, and a second end of the suction pipeline is connected to the suction apparatus, at least one of the suction pipelines is provide with a blocking component at the first end thereof, and the blocking component has a property that can prevent gas from passing through and allow the leaking liquid in the corresponding liquid collecting component to pass through.

In an embodiment, in the leakage protection device, the blocking component is a sealing component to seal the first end, and the sealing component is configured to release a sealing effect when contacting the leaking liquid inside the corresponding liquid collecting component so as to communicate the corresponding liquid collecting component with the suction apparatus.

In an embodiment, in the leakage protection device, the sealing component is made of a material that is dissolvable in the leaking liquid.

In an embodiment, in the leakage protection device, the sealing component is made of a material selected from at least one of salt, oxide, and water-soluble polymer material.

In an embodiment, in the leakage protection device, the sealing component is located inside a cavity of the suction pipeline, or covers the first end from outside.

In an embodiment, in the leakage protection device, the sealing component is in a block structure, and an outer end of the sealing component is located inside or flushed with an end face of the first end, wherein a gap is formed between the end face of the first end and the liquid collecting component, or
the outer end of the sealing component protrudes from the end face of the first end and contacts a bottom face of the liquid collecting component.

In an embodiment, in the leakage protection device, the blocking component is a permeable membrane.

In an embodiment, the leakage protection device further includes:
a sensor, which is arranged inside the liquid collecting component to detect whether there is a leakage; and
a controller, which is connected to the sensor and the suction apparatus to activate the suction apparatus when the sensor detects a leakage.

The leakage protection device provided in the present disclosure includes a suction apparatus, multiple liquid collecting components and multiple suction pipelines. The multiple liquid collecting components are located at different positions of a liquid-cooling heat-dissipation module, respectively, to collect a leaking liquid of the liquid-cooling heat-dissipation module, and the multiple suction pipelines are arranged corresponding to the liquid collecting components, respectively. The first end of each suction pipeline is located inside the corresponding liquid collecting component, and a second end of the suction pipeline is connected to the suction apparatus. At least one of the suction pipelines is provide with a blocking component at the first end, and the blocking component is characteristic of blocking gas from passing through and allowing the leaking liquid in the corresponding liquid collecting component to pass through.

In the leakage protection device provided in the present disclosure, by providing a blocking component, which can block gas from passing through, at the first end of a suction pipeline, when no leaking liquid is collected in a liquid collecting component corresponding to the suction pipeline or the collected leaking liquid does not reach the suction level, the blocking component closes the suction pipeline. Therefore, the leaking liquid in another liquid collecting component can be well drawn through the corresponding suction pipeline when the suction apparatus activates. In addition, when the leaking liquid is collected in a liquid collecting component corresponding to a suction pipeline or the collected leaking liquid reaches the suction level, the blocking component at the first end of the suction pipeline can allow the leaking liquid to enter the suction pipeline through the first end and then be drawn away along the suction pipeline. In summary, the leakage protection device provided in the present disclosure can not only collect and pump leaking liquid through multiple branches, but also quickly draw the leaking liquid when a leakage occurs in one or more branches. The suction efficiency and capacity are improved, providing a longer allowable operation time for emergency operations for the leakage of the liquid-cooling heat-dissipation module.

In order to achieve the above object, a liquid cooling system is further provided in the present disclosure, which includes any leakage protection device described above. The above leakage protection device has the technical effects described above, and thus the liquid cooling system having the above leakage protection device also has the similar technical effects.

In order to achieve the above object, a server is further provided in the present disclosure, including any leakage protection device or liquid cooling system described above. The above leakage protection device or the liquid cooling system has the technical effects described above, and thus the serve having the leakage protection device or the liquid cooling system also has the similar technical effects described above.

### BRIEF DESCRIPTION OF THE DRAWINGS

In order to provide a clear explanation of the embodiments of the present application or the technical solutions in the prior art, a brief introduction will be given to the accompanying drawings required for the description of the embodiments or the prior art. Obviously, the accompanying drawings described below are only some embodiments of the present application. For those skilled in the art, other drawings can be obtained based on these drawings without paying a creative work.

FIG. 1 is a schematic partial-structural view of a leakage protection device according to an embodiment of the present disclosure;

FIG. 2 is a schematic view of an arrangement of a blocking component; and

FIG. 3 is a schematic view of another arrangement of the blocking component.

In the accompany drawings:

| | |
|---|---|
| 1 liquid collecting component, | 2 suction pipeline, |
| 21 blocking component, | 11 liquid cooling plate, |
| 12 liquid inflow or outflow pipe. | |

### DETAILED DESCRIPTION OF THE EMBODIMENTS

A server, a liquid cooling system, and a leakage protection device thereof are provided in embodiments of the present disclosure, which can physically control the on/off of the suction pipeline without a manual operation or an electronic control switch, thereby improving the suction capacity.

The technical solution in the embodiments of the present disclosure will be clearly and completely described in conjunction with the accompanying drawings below. Obviously, the described embodiments are only a part of the embodiments of the present disclosure, not all of them. Based on the embodiments in the present disclosure, all other embodiments obtained by those skilled in the art without paying creative work shall fall within the scope of this present disclosure.

A leakage protection device provided in the present disclosure is applicable for but not limited to collection and pumping of liquid leaking from a liquid-cooling heat-dissipation module of servers. When a leakage occurs in the liquid-cooling heat-dissipation module, the liquid flows into a liquid collecting component through a flow guide pipe and a liquid collecting device, and a suction component is activated at the same time to draw the leaking liquid out of the liquid collecting component. Generally, multiple liquid collecting components are provided, and corresponding suction pipelines are provided. An end of each suction pipeline is located inside the liquid collecting component. One suction apparatus may be provided, that is, a single suction apparatus may be provided for multiple liquid collecting components. When one suction apparatus of a leakage protection device is arranged corresponding to multiple branches, each of which is defined by one suction pipeline being in communication with the corresponding liquid collecting component. In order to improve the suction effect, the inventor of the present disclosure found that a valve may be provided in each branch and can be controlled manually or electrically so that some branches are in communication and the other branches are disconnected during suction. It can be understood that the term “communication” here refers to the communication between the liquid collecting component and the suction apparatus through the corresponding suction pipeline(s). The term “disconnection” refers to disconnection between the liquid collecting component and the suction apparatus through the suction pipeline. However, inside the server, manually controlling valve may affect the timeliness of drawing the leaking liquid, and electrically controlling valve may be costly and introduce many control units and wirings into the server, resulting in complex and unsightly wirings. Moreover, there is no good solution to the above technical problem for a multi-branch drawing structure that is not appropriate to mount valves or has a high cost for mounting valves.

The leakage protection device provided in the present disclosure is suitable for the case of a single suction apparatus corresponding to multiple branches, and can physically control communication or disconnection of the suction pipeline, so as to at least partially solve the problems such as high cost and complex and unsightly overall wirings caused in the case of opening or closing a valve in detection of pipeline leakage, or a poor suction capacity in the case of having no valve.

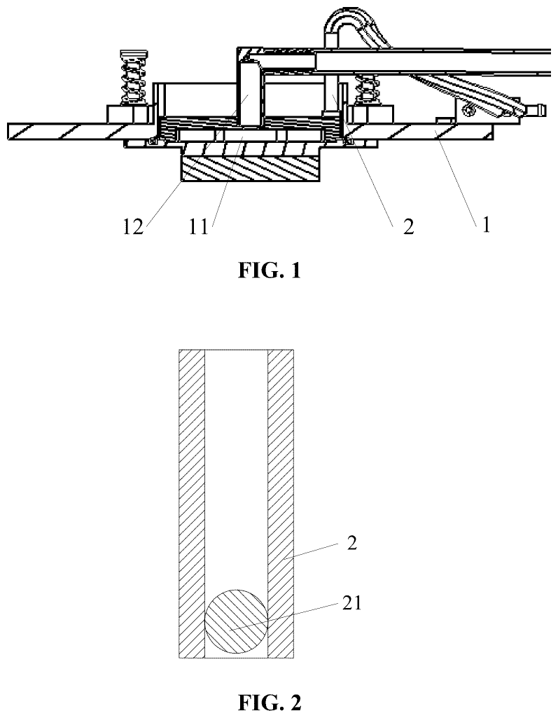

In an embodiment, referring to FIGS. 1 and 2, the leakage protection device provided in the present disclosure includes: a suction apparatus, a liquid collecting component 1, and a suction pipeline 2. The suction apparatus is a power apparatus for the leakage protection device and is used to provide a negative pressure to draw the leaking liquid collected in the liquid collecting component 1 through the suction pipeline 2 to a storage device or the outside of the liquid-cooling heat-dissipation module.

The number of both the liquid collecting component 1 and the suction pipeline 2 is multiple. The term “multiple” herein refers to two or more. The multiple liquid collecting components 1 are respectively located at different positions of the liquid-cooling heat-dissipation module to collect the leaking liquid at different positions of the liquid-cooling heat-dissipation module. The locations of the liquid collecting components 1 can be accordingly set according to the positions of the liquid-cooling heat-dissipation module where leakage is prone to occur, for example, at a liquid cooling plate 11 of the liquid-cooling heat-dissipation module, at a liquid inflow or outflow pipe 12 connected to the liquid cooling plate 11, at a joint between the liquid inflow or outflow pipe 12 and the liquid cooling plate 11, or at a water distributor or collector.

The multiple suction pipelines 2 are respectively arranged corresponding to various liquid collecting components 1. Specifically, at least one suction pipeline 2 is arranged corresponding to one of the liquid collecting components 1. A first end of each suction pipeline 2 is located inside the corresponding liquid collecting component 1, and a second end thereof is connected to the suction apparatus. At least one suction pipeline 2 has a blocking component 21 at its first end. The blocking component 21 is configured to block gas from passing through and allow a leaking liquid in the corresponding liquid collecting component 1 to pass through. It should be noted that the blocking component 21 in the present disclosure utilizes its own physical or chemical properties to block gas from passing through, and automatically allows the leaking liquid collected in the liquid collecting component 1 to pass through. That is, the property of the blocking component 21 is such as to block passage of gas and allow passage of the leaking liquid from the corresponding liquid collecting component 1. It shall be noted that the term “property” here includes the physical or chemical properties of the blocking component 21 itself. That is, the communication or disconnection of the suction pipeline 2 is not achieved by the manual operation or under an electrical control. The blocking effect of the blocking component 21 on gas refers to the ability to block gas from passing through before encountering liquid. There is no limitation as to whether the blocking component 21 can block gas after encountering liquid.

In the leakage protection device provided in the present disclosure, by providing the blocking component 21, which can block gas from passing through, at the first end of the suction pipeline 2, the blocking component 21 closes the suction pipeline 2 if no leaking liquid is collected in the liquid collecting component 1 corresponding to the suction pipeline 2 or if the collected leaking liquid does not reach the suction level, and when the suction apparatus is activated, it can well draw the leaking liquid in another liquid collecting component 1 through a corresponding suction pipeline 2. In addition, when the leaking liquid is collected in the liquid collecting component 1 corresponding to the suction pipeline 2 or when the collected leaking liquid reaches the suction level, the blocking component 21 at the first end of the suction pipeline 2 can allow the leaking liquid to enter the suction pipeline 2 through the first end and then be drawn away along the suction pipeline 2. In summary, the leakage protection device provided in the present disclosure can collect and pump leaking liquid through multiple branches and can quickly draw the leaking liquid when a leakage occurs in one or more branches. The suction efficiency and capacity are improved, providing a longer allowable operation time for emergency operations for the leakage of the liquid-cooling heat-dissipation module.

In some embodiments, the blocking component 21 is a sealing component used to seal the first end and to unseal when contacting the leaking liquid inside the corresponding liquid collecting component 1 so as to communicate the corresponding liquid collecting component 1 with the suction apparatus. In this embodiment, the blocking component 21 is a sealing component, which is disposable. When the sealing component does not come into contact with the leaking liquid, it can maintain its original state to block the suction pipeline 2, so as to disconnect the liquid collecting component 1 from the suction apparatus. When the sealing component comes into contact with the leaking liquid, it changes in state and thus releases the blocking effect on the first end, so that the liquid collecting component 1 is in communication with the suction apparatus. By utilizing the state change, the sealing component prevents the gas from passing through or allows the leaking liquid to pass through during liquid leakage. The structure is simple and reliable.

In some embodiments, the sealing component is made of a material that can dissolve in the leaking liquid, i.e., a material that dissolves when encountering the leaking liquid. The suction pipeline 2 corresponding to the liquid collecting component 1 having no leaking liquid is still blocked, whereas the sealing component in the suction pipeline 2 corresponding to the liquid collecting component 1 having leaking liquid will quickly dissolve when encountering the leaking liquid, so that this suction pipeline 2 is communicated with the suction apparatus which can quickly draw the leaking liquid from the liquid collecting component 1 to decrease the damage to the internal part of the server caused by the leakage. The sealing component is made of a material that dissolves easily in the leaking liquid, resulting in a simple structure, low cost, and easy assembly with the suction pipeline 2. The material of the sealing component may be selected from at least one of salt, oxide, or water-soluble polymer materials. In other embodiments, the sealing component may be made of a material that can release the sealing effect by being broken or reduced in volume when encountering the leaking liquid. Alternatively, the sealing component may be a solid that can undergo a chemical change upon contacting with the leaking liquid and then be transformed into a liquid.

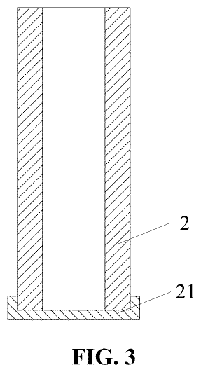

In some embodiments, referring to FIG. 2, the sealing component may be located inside the cavity of the suction pipeline 2. Alternatively, referring to FIG. 3, the sealing component may cover the first end from outside. By being disposed inside the cavity of the first end or covering the first end from outside, the sealing component can block gas from passing through and unblock when encountering the leaking liquid. Arranging the sealing component inside the cavity of the first end, the assembly may be performed easily. Arranging the sealing component to cover the first end from outside, it is easy to observe the use status of the sealing component.

In some embodiments, the sealing component is in a block structure, and the outer end of the sealing component is located inside or flush with the end face of the first end. In addition, there is a gap between the end face of the first end and the liquid collecting component 1. With this gap, the leaking liquid can come into contact with the sealing component to release the sealing effect.

In some embodiments, the outer end of the sealing component protrudes from the end face of the first end and contacts the bottom face of the liquid collecting component 1. It can be understood that the sealing component may partially protrude outside the end face of the first end if it is located inside the cavity of the first end, or the sealing component naturally may be outside the end face of the first end if it covers the first end. The sealing component is arranged to be in contact with a bottom face of the liquid collecting component 1. Thus, once there is leaking liquid on the bottom face, the sealing component can quickly come into contact with the leaking liquid, thereby communicating the liquid collecting component 1 with the suction apparatus to quickly remove the leaking liquid. In other embodiments, the outer end of the sealing component may be distanced from the bottom face of the liquid collecting component 1 by a spacing distance, so that the sealing component can come into contact with the leaking liquid only when a certain amount of leaking liquid is reached, i.e., only when the leaking liquid reaches the suction level corresponding to the spacing distance.

In some embodiments, the blocking component 21 is a permeable membrane. The permeable membrane refers to a membrane that blocks gas from passing through and allows liquid to pass through. The permeable membrane may be a hollow fiber ultrafiltration membrane, etc. The permeable membrane is provided at the first end of the suction pipeline, which can both block gas from passing through and allow the leaking liquid to pass through. The permeable membrane may be bonded inside the first end of the suction pipeline, or may be arranged to wrap and be bonded to the first end of the suction pipeline from outside.

In some embodiments, the leakage protection device may further include a sensor and a controller. The sensor may be arranged in the liquid collecting component 1 to detect whether there is a leakage. The controller is connected to both the sensor and the suction apparatus to activate the suction apparatus when the sensor detects a leakage. When a leakage occurs in the liquid-cooling heat-dissipation module, the sensor detects the leakage and transmits a leakage signal to the controller, and optionally triggers an alarm. The controller may be arranged on the host or collector to trigger an alarm. Meanwhile, the controller may activate the suction apparatus. The leaking liquid is collected into one or more liquid collecting components 1 along the collection structure. The sealing component of the suction pipeline 2 in the liquid collecting component 1 quickly undergoes a state change, for example, dissolving, to unseal when encountering the liquid. The suction pipeline 2 is communicated, and the leaking liquid can leave from the interior of server through the suction pipeline 2, thereby decreasing the damage of leakage to the hardware and information of the server and increasing the allowable maintenance time for maintenance personnel

Based on the leakage protection device provided in the above embodiments, a liquid cooling system is further provided in the present disclosure, which includes the leakage protection device in any one of the above embodiments. The liquid cooling system adopts the leakage protection device in the above embodiments, and brings about the beneficial effects as described in the above embodiments.

A server is further provided in the present disclosure, including the leakage protection devices or the liquid cooling system in any one of the above embodiments. The server adopts the leakage protection device or the liquid cooling system in the above embodiments, and brings about the beneficial effects as described in the above embodiments.

The various embodiments in the present disclosure are described in a progressive manner, with each embodiment emphasizing its differences from other embodiments. The same and similar parts among the embodiments can refer to each other.

The above description of the disclosed embodiments enables those skilled in the art to carry out or use the present disclosure. Various modifications to these embodiments will be apparent to those skilled in the art, and the general principles defined in the present disclosure can be applied in other embodiments without departing from the spirit or scope of the present disclosure. Therefore, the present disclosure should not be limited to the embodiments shown in the description, but will conform to the broadest scope consistent with the principles and novel features disclosed in the present application.

1. A leakage protection device, comprising:
a suction apparatus;
a plurality of liquid collecting components located at different positions of a liquid-cooling heat-dissipation module, respectively, to collect a leaking liquid of the liquid-cooling heat-dissipation module; and
a plurality of suction pipelines arranged corresponding to the liquid collecting components, respectively, wherein
each suction pipeline has a first end located inside the corresponding liquid collecting component, and a second end connected to the suction apparatus,
at least one of the suction pipelines is provided with a blocking component at the first end thereof, and the blocking component has a property that can prevent passage of gas and allow passage of the leaking liquid in the corresponding liquid collecting component.

2. The leakage protection device according to claim 1, wherein the blocking component is a sealing component for sealing the first end, and the sealing component is configured to unseal when contacting the leaking liquid inside the corresponding liquid collecting component so as to communicate the corresponding liquid collecting component with the suction apparatus.

3. The leakage protection device according to claim 2, wherein the sealing component is made of a material that is dissolvable in the leaking liquid.

4. The leakage protection device according to claim 2, wherein the sealing component is made of a material selected from at least one of salt, oxide, and water-soluble polymer material.

5. The leakage protection device according to claim 2, wherein the sealing component is located inside a cavity of the suction pipeline, or covers the first end from outside.

6. The leakage protection device according to claim 5, wherein the sealing component is in a block structure, and an outer end of the sealing component is located inside or flush with an end face of the first end, wherein a gap is formed between the end face of the first end and the liquid collecting component, or
the outer end of the sealing component protrudes from the end face of the first end and contacts a bottom face of the liquid collecting component.

7. The leakage protection device according to claim 1, wherein the blocking component is a permeable membrane.

8. The leakage protection device according to claim 1, further comprising:
a sensor arranged at the liquid collecting component to detect whether there is a leakage; and
a controller connected to the sensor and the suction apparatus to activate the suction apparatus when the sensor detects a leakage.

9. The leakage protection device according to claim 3, wherein the sealing component is located inside a cavity of the suction pipeline, or covers the first end from outside.

10. The leakage protection device according to claim 4, wherein the sealing component is located inside a cavity of the suction pipeline, or covers the first end from outside.

11. The leakage protection device according to claim 9, wherein the sealing component is in a block structure, and an outer end of the sealing component is located inside or flush with an end face of the first end, wherein a gap is formed between the end face of the first end and the liquid collecting component, or
the outer end of the sealing component protrudes from the end face of the first end and contacts a bottom face of the liquid collecting component.

12. The leakage protection device according to claim 10, wherein the sealing component is in a block structure, and an outer end of the sealing component is located inside or flush with an end face of the first end, wherein a gap is formed between the end face of the first end and the liquid collecting component, or
the outer end of the sealing component protrudes from the end face of the first end and contacts a bottom face of the liquid collecting component.

13. The leakage protection device according to claim 2, further comprising:
a sensor arranged at the liquid collecting component to detect whether there is a leakage; and
a controller connected to the sensor and the suction apparatus to activate the suction apparatus when the sensor detects a leakage.

14. The leakage protection device according to claim 3, further comprising:
a sensor arranged at the liquid collecting component to detect whether there is a leakage; and
a controller connected to the sensor and the suction apparatus to activate the suction apparatus when the sensor detects a leakage.

15. The leakage protection device according to claim 4, further comprising:
a sensor arranged at the liquid collecting component to detect whether there is a leakage; and
a controller connected to the sensor and the suction apparatus to activate the suction apparatus when the sensor detects a leakage.

16. A liquid cooling system, comprising the leakage protection device according to claim 1.

17. A server, comprising the liquid cooling system according to claim 16.
